(19) United States
(12) Patent Application Publication
(10) Pub. No.: US 2007/0166863 A1
(43) Pub. Date: Jul. 19, 2007

(54) Method for forming mirror devices for a digital light process apparatus

(75) Inventor: Duck-Joong Kim, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Dongbu Electronics Co., Ltd.

(21) Appl. No.: 11/645,532

(22) Filed: Dec. 27, 2006

(30) Foreign Application Priority Data
Dec. 29, 2005 (KR) 10-2005-0133831

(51) Int. Cl. H01L 21/00

(52) U.S. Cl. 438/48

(57) ABSTRACT

A method for forming mirror devices for a DLP apparatus. The method includes: forming a lower metal layer as wiring for driving a micromirror that perform light switching operation on a screen sensor; forming a lower inter-metal dielectric layer over the lower metal layer; forming a light path blocking plate on the lower inter-metal dielectric to cover the lower metal layer; forming an upper inter-metal dielectric over the light path blocking plate; forming an upper metal layer on the upper inter-metal dielectric layer as additional wiring; and forming a surface ARC layer over the upper metal layer.

### RELATED APPLICATION

This application is based upon and claims the benefit of priority to Korean Application No. 10-2005-0133831, filed on Dec. 29, 2005, the entire contents of which are incorporated herein by reference.

### TECHNICAL FIELD

The present invention relates to a Digital Light Process (DLP), and more particularly, to a method for forming mirror devices which may improve the performance of a DLP apparatus, which includes the mirror devices.

### BACKGROUND

A DLP apparatus typically includes a semiconductor light switch unit having a structure in which finely driven mirrors are integrated under a screen sensor. The DLP apparatus represents brightness or darkness for each pixel of the screen sensor by finely driving the mirrors.

FIGS. 1 and 2 schematically illustrate a conventional DLP apparatus, and FIG. 3 schematically illustrates the structure of a mirror device for the conventional DLP apparatus.

Referring to FIGS. 1 and 2, the conventional DLP apparatus includes a semiconductor light switch unit 40 disposed under a screen sensor 10. Semiconductor light switch unit 40 includes a mirror drive unit 20, which may be a semiconductor device having Static Random Access Memory (SRAM) devices integrated therein, and micromirrors 30 integrated on mirror drive unit 20 using Micro-ElectroMechanical System (MEMS) technology.

Micromirrors 30 are finely driven mirrors, that is, aluminum alloy fine mirrors having a size of about 16 μm. Micromirrors 30 are formed above their respective SRAM devices for SRAM cells, and have an inclination angle of about 10 degrees in an ON/OFF state. Micromirrors 30 operate in response to the electrostatic fields generated by the SRAM cells disposed immediately under micromirrors 30. One may adjust the time for light projected onto micromirrors 30 to be reflected or not to be reflected from micromirrors 30, so that the brightness corresponding to an accumulated time value is sensed by human eyes. Therefore, the brightness/darkness for each of the pixels of screen sensor 10 may be represented.

However, as shown in FIG. 2, when, in an OFF state, incident light beams are reflected in a scattered reflection manner from the surface of mirror drive unit 20 disposed below micromirrors 30, the light beams reflected in a scattered reflection manner are then incident on screen sensor 10. Thus, the contrast performance of the DLP apparatus is degraded.

As shown in FIG. 3, the above-described scattered reflection is caused by a second metal layer 21 and a third metal layer 25, which belong to the three metal layers of the SRAM cells that are integrated to constitute mirror drive unit 20.

Referring to FIG. 3, mirror drive unit 20 is formed in an SRAM cell structure, and is constructed using three metal layers to configure the SRAM cells. The SRAM cells are implemented by electrically connecting transistors, which are formed on a substrate, through connecting wiring. In this case, the connecting wiring may be formed in a three-metal-layer structure. That is, a first inter-metal dielectric layer is formed on a first metal layer (not shown), and second metal layer 21 is formed on the first inter-metal dielectric layer.

Second metal layer 21 may be made of an aluminum-copper (Al—Cu) alloy. A second Anti-Reflective Coating (ARC) layer 22, which is made of a titanium nitride (TiN) layer, is formed on second metal layer 21. A second inter-metal dielectric layer 23 is formed on second metal layer 21, and a third metal layer 25, which is made of an aluminum-silicon-titanium (Al—Si—Ti) alloy, is formed on second inter-metal dielectric layer 23. A third ARC layer 27 for third metal layer 25 is formed on third metal layer 25.

A recess groove 28 is formed in an upper portion of second inter-metal dielectric layer 23, which is disposed over second metal layer 21, by patterning third ARC layer 27 and third metal layer 25. A surface ARC layer 29, which is made of a silicon oxide (SiO₂) layer, is formed on third ARC layer 27, and in recess groove 20 over the surface of second inter-metal dielectric 23.

In the structure of mirror drive unit 20 described above, light beams reflected from below third metal layer 25 in a scattered reflection manner are almost trapped by second ARC layer 27 and surface ARC layer 29 due to destructive interference between the light beams. Thus, the light beams reflected in a scattered reflection manner are not actually radiated. Although the destructive interference should occur between light beams, which are reflected from second metal layer 21 in a scattered reflection manner, however, destructive interference may not actually occur due to the thickness of second inter-metal dielectric 23. Accordingly, the light beams reflected in a scattered reflection manner may be incident between the patterns of third metal layer 25, and may be reflected therefrom. Accordingly, the overall contrast performance of the DLP apparatus relies on the destructive interference.

Accordingly, it is necessary to develop a method for alleviating the degradation of contrast performance of the DLP apparatus, which is caused by light beams reflected from second metal layer 21 in a scattered reflection manner.

### SUMMARY

Consistent with the present invention, there is provided a method for forming mirror devices for a DLP apparatus, which may improve the performance of a DLP apparatus, which includes the mirror devices.

In one embodiment, the method for forming mirror devices for a DLP apparatus includes forming a lower metal layer as wiring for driving a micromirror that perform light switching operation on a screen sensor; forming a lower inter-metal dielectric layer over the lower metal layer; forming a light path blocking plate on the lower inter-metal dielectric to cover the lower metal layer; forming an upper inter-metal dielectric layer over the light path blocking plate; forming an upper metal layer on the upper inter-metal dielectric layer as additional wiring; and forming a surface ARC layer over the upper metal layer.

The step of forming the light path blocking plate may include forming an opaque metal layer on the lower inter-metal dielectric; and patterning the opaque metal so that the opaque metal covers the lower metal layer without extending to a position under the upper metal layer.

The opaque metal layer may be formed by depositing a titanium nitride layer to a thickness of 600 Å or more.

The method may further include patterning the upper metal layer through an etching process, the etching process for forming the upper metal layer being terminated at a location of light path blocking plate.

The upper inter-metal dielectric may be planarized through a Chemical Mechanical Polishing (CMP) process so that the light path blocking plate having a thickness of about 1000 Å remains.

Consistent with the present invention, there is also provided a DLP apparatus. The DLP apparatus includes a screen sensor; a plurality of micromirrors for performing light switch operation on the screen sensor; and a mirror drive unit for driving the micromirrors, the mirror drive unit comprising a lower metal layer formed as wiring for driving one of the micromirror, a lower inter-metal dielectric layer formed over the lower metal layer, a light path blocking plate formed on the lower inter-metal dielectric to cover the lower metal layer, an upper inter-metal dielectric layer formed on the lower inter-metal dielectric layer, the upper inter-metal dielectric layer being patterned to expose the light path blocking plate, an upper metal layer formed on the upper inter-metal dielectric layer as additional wiring, and a surface ARC layer formed to cover the upper metal layer.

The light path blocking plate may include a titanium nitride layer having a thickness of 600 Å or more.

The surface ARC layer may include a silicon oxide layer having a thickness of 500 to 700 Å so that visible light having wavelengths ranging from 450 to 550 nm may be canceled through destructive interference.

The method for forming mirror devices for a DLP apparatus mayimprove the performance of the DLP apparatus, which includes the mirror devices.

### BRIEF DESCRIPTION OF THE DRAWINGS

The above and other features consistent with the present invention will become apparent from the following description of preferred embodiments, given in conjunction with the accompanying drawings, in which:

FIGS. 1 and 2 schematically illustrate a conventional DLP apparatus;

FIG. 3 schematically illustrate the structure of a mirror device for the conventional DLP apparatus; and

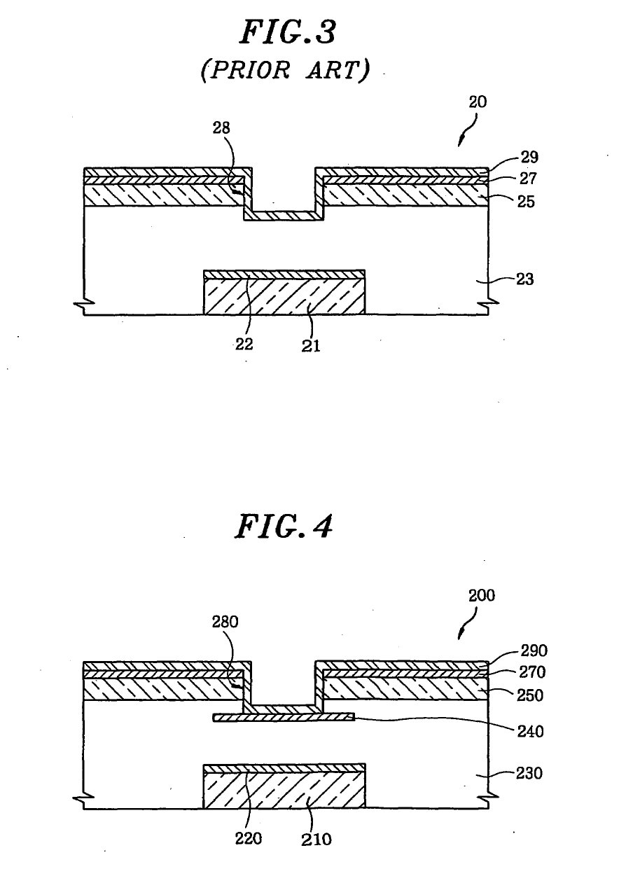

FIGS. 4 and 5 schematically illustrate a method for forming mirror devices for a DLP apparatus, consistent with an embodiment of the present invention.

### DETAILED DESCRIPTION

Hereinafter, a preferred embodiment consistent with the present invention will be described in detail with reference to the accompanying drawings.

In an embodiment, in order to prevent a second metal layer disposed under a third metal layer from causing a scattered reflection, a light path blocking plate, which is preferably formed of a titanium nitride layer, may be formed above the second metal layer. Accordingly, the scattered reflection caused by the second metal layer may be effectively prevented, and thus the contrast performance of the DLP apparatus may be improved.

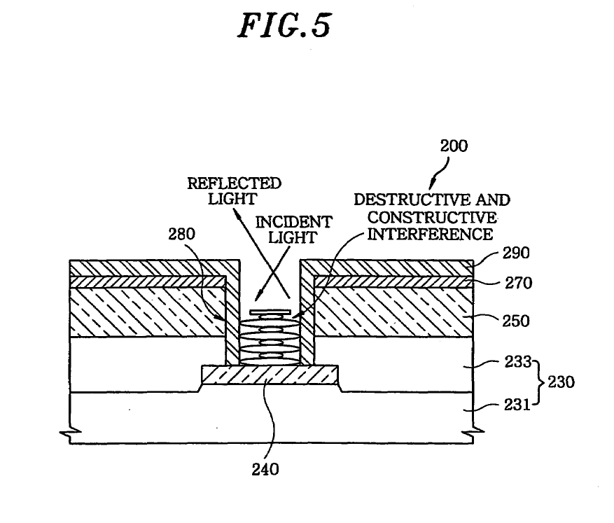

FIGS. 4 and 5 schematically illustrate a method for forming mirror devices for a DLP apparatus, consistent with an embodiment of the present invention.

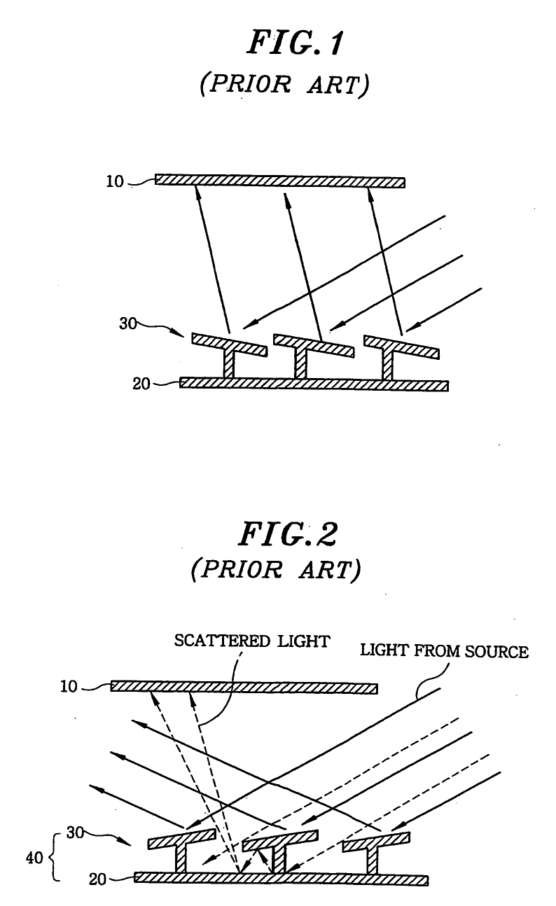

Hereinafter, the method for forming mirror devices for a DLP apparatus, consistent with an embodiment of the present invention, is described with reference to FIGS. 4 and 5. In a mirror drive unit 200, which includes SRAM devices for driving mirrors (reference numeral 20 in FIG. 1) that performs light switching operation on a screen sensor (reference numeral 10 in FIG. 1), a second metal layer 210, that is, a lower metal layer 210, is formed, which includes a three-metal layer structure for the SRAM devices. An etching process for patterning lower metal layer 210 is performed and, thereafter, a lower inter-metal dielectric layer 231, that is, a first inter-metal dielectric layer 231, is formed over the patterned lower metal layer 210.

Lower metal layer 210 may be made of an aluminum-copper alloy, and a first ARC layer 220, which may be formed of a titanium nitride layer, is formed on lower metal layer 210 during a photolithography process conducted when patterning is performed to prevent scattered reflection from occurring. Lower inter-metal dielectric layer 231, which is formed above lower metal layer 210, is planarized using a CMP process.

A light path blocking plate 240 is formed on lower inter-metal dielectric 231 to cover lower metal layer 210. Light path blocking plate 240 is formed by depositing a titanium nitride layer to a thickness of 600 Å or more, so as to function as an opaque metal layer. Thereafter, the titanium nitride layer is patterned such that it covers lower metal layer 210 and does not extend to a position below upper metal layer 250.

Upper inter-metal dielectric 233, which is formed over light path blocking plate 240, is formed by depositing an oxide layer to a thickness of about 1000 Å or more, and is planarized using a CMP process such that the thickness thereof is reduced to below 1000 Å. Thereafter, an upper metal layer 250, that is, a third inter-metal dielectric layer 250, is deposited on the resultant product and patterned. In this case, a process of patterning and etching to form a via, and a process of forming a connection contact by filling the via with a barrier metal layer and a tungsten (W) material using a Chemical Vapor Deposition (CVD) method may be performed further.

Upper metal layer 250 may be made of an aluminum-silicon-titanium alloy, and a second ARC layer 270, which may be formed of a titanium nitride layer, is formed during a photolithography process conducted when patterning is performed to prevent scattered reflection from occurring. Upper metal layer 250 is patterned using an etching process, thereby exposing lower metal layer 210 between the patterns of upper metal layer 250. In this case, the etching process is terminated at a location of light path blocking plate 240, and thus light path blocking plate 240 having a thickness of 600 Å or more remains. A structure having a recess groove 280 is formed above light path blocking plate 240 through the above-described patterning process.

Thereafter, surface ARC layer 290, which may be a silicon oxide layer, for preventing scattered reflection from occurring, is formed on the surface of mirror drive unit 200, so that visible light having wavelengths ranging from 450 to 550 nm may be optimally cancelled through destructive interference.

Mirror drive unit 200 thus formed may cause incident light beams to be trapped without being reflected, because the incident light beams are not reflected due to destructive interference caused by light path blocking plate 240. Accordingly, the scattered reflection caused by lower metal layer 210 may be prevented, so that, when micromirrors 30 enter an OFF state, the scattered reflection of the light beams from screen sensor 30 may be effectively prevented, as shown in FIG. 2. Therefore, the contrast performance of the DLP apparatus may be improved.

Consistent with the present invention described above, light path blocking plate 240 may be formed of a titanium layer, which is formed on second metal layer 210, so that destructive interference caused by second metal layer 210 may be effectively prevented. Accordingly, the contrast performance, which represents the definition of the DLP apparatus, may be improved.

Although the preferred embodiment consistent with the present invention has been disclosed for illustrative purposes, those skilled in the art will appreciate that various modifications, additions, and substitutions are possible, without departing from the scope and spirit of the invention as defined in the accompanying claims.

What is claimed is:

1. A method for forming mirror devices for a Digital Light Process (DLP) apparatus, the method comprising:
forming a lower metal layer as wiring for driving a micromirror that perform a light switching operation on a screen sensor;
forming a lower inter-metal dielectric layer over the lower metal layer;
forming a light path blocking plate on the lower inter-metal dielectric to cover the lower metal layer;
forming an upper inter-metal dielectric layer over the light path blocking plate;
forming an upper metal layer on the upper inter-metal dielectric layer as additional wiring; and
forming a surface Anti-Reflective Coating (ARC) layer over the upper metal layer.

2. The method of claim 1, wherein forming the light path blocking plate comprises:
forming an opaque metal layer on the lower inter-metal dielectric layer; and
patterning the opaque metal layer so that the opaque metal layer covers the lower metal layer without extending to a position under the upper metal layer.

3. The method of claim 2, wherein forming the opaque metal layer comprises depositing a titanium nitride layer to a thickness of 600 Å or more.

4. The method of claim 1, further comprising patterning the upper metal layer through an etching process, the etching process being terminated at a location of the light path blocking plate.

5. The method of claim 1, wherein the upper inter-metal dielectric layer is planarized through a chemical mechanical polishing (CMP) process so that the light path blocking plate having a thickness of about 1000 Å remains.

6. A digital light process (DLP) apparatus, comprising:
a screen sensor;
a plurality of micromirrors for performing a light switch operation on the screen sensor; and
a mirror drive unit for driving the micromirrors, the mirror drive unit further comprising:
a lower metal layer for driving one of the micromirrors,
a lower inter-metal dielectric layer formed over the lower metal layer,
a light path blocking plate formed on the lower inter-metal dielectric covering the lower metal layer,
an upper inter-metal dielectric formed on the lower inter-metal dielectric, the upper inter-metal dielectric layer being patterned to expose the light path blocking plate,
an upper metal layer formed on the patterned upper inter-metal dielectric layer as additional wiring, and
a surface anti-reflective coating (ARC) layer covering the upper metal layer.

7. The apparatus of claim 6, wherein the light path blocking plate comprises a titanium nitride layer having a thickness of about 600 Å or more.

8. The apparatus of claim 6, wherein the surface ARC layer comprises a silicon oxide layer having a thickness of about 500 to 700 Å so that visible light wavelengths ranging from 450 to 550 nm may be canceled through destructive interference.
